(19) United States
(12) Patent Application Publication
(10) Pub. No.: US 2005/0225413 A1
(43) Pub. Date: Oct. 13, 2005

(54) Microelectromechanical structures, devices including the structures, and methods of forming and tuning same

(76) Inventors: Michael N. Kozicki, Phoenix, AZ (US); Anthony Walton, Edinburgh (GB); Stefan Enderling, Edinburgh (GB)

Correspondence Address: SNELL & WILMER;ONE ARIZONA CENTER, 400 EAST VAN BUREN, PHOENIX, AZ, 850040001, US

(21) Appl. No.: 11/145,745

(22) Filed: Jun. 6, 2005

Related U.S. Application Data
(63) Continuation-in-part of application No. 10/934,840, filed on Sep. 3, 2004.
(63) Continuation-in-part of application No. 10/282,902, filed on Oct. 28, 2002.
(60) Provisional application No. 60/500,136, filed on Sep. 3, 2003.
(60) Provisional application No. 60/339,604, filed on Oct. 26, 2001.

(51) Int. Cl. H01L 21/00

(52) U.S. Cl. 335/78

(57) ABSTRACT

A microelectromechanical structure and device and methods of forming and using the structure and device are disclosed. The structure includes a mechanical element, an ion conductor and a plurality of electrodes. Mechanical properties of the structure are altered by applying a bias across the electrodes. Such structures can be used to form devices such as resonators for RF applications.

### CROSS REFERENCE TO RELATED APPLICATIONS

This application is a continuation-in-part of application Ser. No. 10/934,840, entitled MICROMECHANICAL STRUCTURE, DEVICE INCLUDING THE STRUCTURE, AND METHODS OF FORMING AND USING SAME, which claims the benefit of U.S. patent application Ser. No. 60/500,136, entitled PROGRAMMABLE METALLIZATION CELL TECHNOLOGY IN MICROACTUATORS AND AIR GAP SWITCHES, filed Sep. 3, 2003, and is a continuation-in-part of U.S. patent application Ser. No. 10/282,902, entitled TUNABLE CANTILEVER APPARATUS AND METHOD OF MAKING SAME, filed Oct. 28, 2002, which claims priority to Provisional Application Ser. No. 60/339,604, entitled APPLICATIONS OF PROGRAMMABLE METALLIZATION CELL TECHNOLOGY, filed Oct. 26, 2001; the contents of which are incorporated herein.

### FIELD OF INVENTION

The present invention generally relates to microelectromechanical structures and to devices including the structures. More particularly, the invention relates to microelectromechanical structures that can be tuned or manipulated by growing or dissolving an electrodeposit on portions of the structures.

### BACKGROUND OF THE INVENTION

Microeletromechanical systems (MEMS) generally include mechanical elements that are flexible and that are movable by magnetic, electric, thermal, or other force. Such systems often include a cantilever or beam element that can sense movement or that can be caused to move upon application of a suitable force. For example, plates, cantilever and beam MEMS can be used for applications such as acceleration sensors, vibrators, radiation detectors, micro mirrors, and resonators.

Use of plate, disk, ring, comb, frame, tuning fork, cantilever and beam MEMS as resonators are particularly desirable because of the high Q factors associated with such devices. However, manufacturing resonators with well-defined resonant frequencies is relatively difficult. In particular, nanoscale statistical irregularities caused by the nature of the materials in the resonators and manufacturing variations in deposition, lithography, and etch methods lead to significant variation in mass and stiffness of the mechanical structures. The variations in mass and stiffness, in turn, lead to differences of the resonant frequencies of the structures. Additionally, environmental factors such as oxidation, condensation of airborne vapors and contamination can alter the vibrating mass after the structure has been fabricated.

Accordingly, improved microelectromechanical structures and devices including the structures that can be tune or manipulated after manufacture of the devices and structures and methods of tuning the structures and devices are desired.

### SUMMARY OF THE INVENTION

The present invention provides improved microelectromechanical structures and devices including the structures. More particularly, the invention provides MEMS devices and structures that can be tuned by growing or dissolving an electrodeposit proximate a movable mechanical element, and methods of forming, tuning, and using the structures and devices.

In accordance with one exemplary embodiment of the present invention, a microelectromechanical structure includes a base, a movable mechanical element coupled to the base, an ion conductor formed on or proximate at least a portion of the base, and at least two electrodes. The structure is configured such that when a bias is applied across two electrodes, an electrodeposit forms in a specified location which may be near one of the electrodes, thereby altering a distribution of mass near the mechanical element. In accordance with one aspect of this embodiment, the movable mechanical element is a beam. In accordance with other aspects, the mechanical element is a cantilever, a comb structure, plate, disk, ring, frame or a tuning fork.

In accordance with another exemplary embodiment of the invention, a microelectromechanical structure includes a base, a movable mechanical element coupled to the base, and at least three electrodes-one soluble electrode and two inert electrodes. The structure is configured such that when one inert electrode and the soluble electrode are similarly biased compared to the other inert electrode, an electrodeposit forms between the two inert electrodes.

In accordance with another embodiment of the invention, a resonator includes a base, a movable mechanical element attached to the base, an ion conductor, and two or more electrodes formed on or proximate the ion conductor.

In accordance with yet another embodiment of the invention, a method of tuning a MEMS device includes providing a base; providing a mechanical element coupled to the base; providing an ion conductor on a portion of the base; providing electrodes on the ion conductor; and applying a bias across the electrodes to cause an electrodeposit to form near one of the electrodes, thereby altering a distribution of mass on the base. The mechanical element attached to such a base can be a beam, cantilever, comb , doubled ended tuning fork, disk, ring, frame structure capable to vibrate in at least one of the available modes.

### BRIEF DESCRIPTION OF THE DRAWINGS

A more complete understanding of the present invention may be derived by referring to the detailed description and claims, considered in connection with the figures, wherein like reference numbers refer to similar elements throughout the figures, and:

FIG. 1 illustrates a microelectromechanical structure formed on a surface of a substrate in accordance with one embodiment of the present invention;

FIG. 2 illustrates a microelectromechanical structure in accordance with an another embodiment of the present invention;

FIG. 3, illustrates a microelectromechanical structure in accordance with yet another embodiment of the present invention;

FIG. 4, illustrates a microelectromechanical structure in accordance with yet a further embodiment of the present invention; and

FIGS. 5(a)-5(c) illustrate a microelectromechanical structure in accordance with a further embodiment of the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

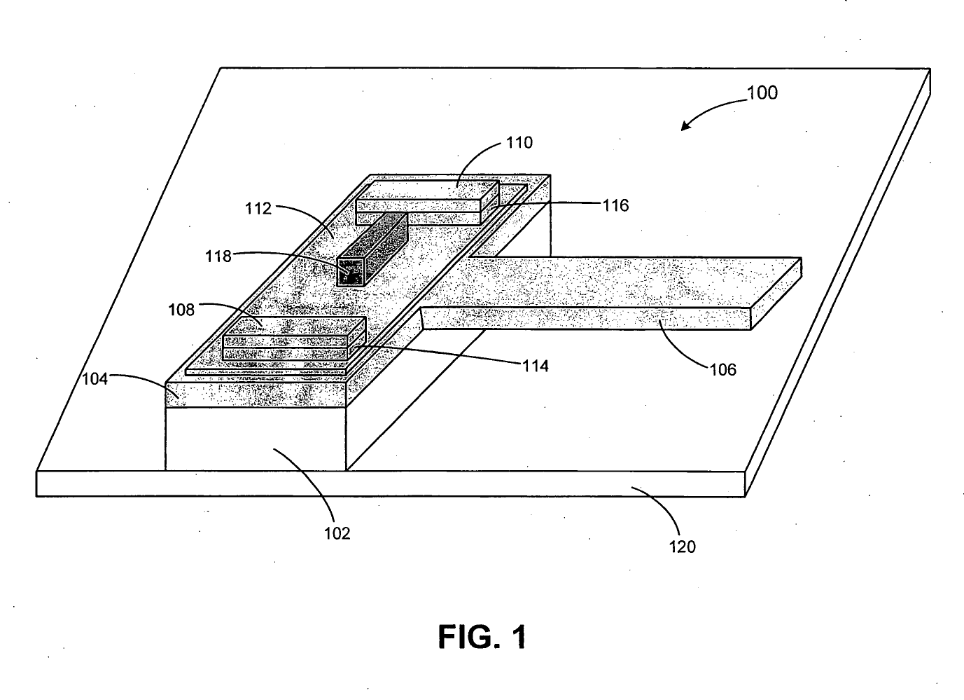

FIG. 1 illustrates a microelectromechanical device 100 formed on a surface of a substrate 120 in accordance with an exemplary embodiment of the present invention. Device 100 includes a support 102, a base 104, a mechanical element 106, electrodes 108 and 110, an ion conductor 112, and optionally includes buffer or barrier layers 114 and 116. As will be discussed in greater detail below, device 100 can be used to form devices such resonators and the like. Device 100 is advantageous compared to conventional microelectromechanical devices because, among other reasons, device 100 can be tuned or manipulated by altering an amount of mass on base 104 proximate element 106. By altering a mass distribution on base 104, stress fields in element 106 can be manipulated, and thus a resonant frequency of the device can be altered. In this manner, a resonant frequency of device 100 can be altered, while maintaining the high Q factor of the device.

During a tuning operation, mechanical properties of device 100 are altered by applying a bias greater than a threshold voltage (V_{T}), discussed in more detail below, across electrodes 108 and 110, which is sufficient to cause conductive material within ion conductor 112 to migrate. For example, as a voltage V≧V_{T} is applied across electrodes 108 and 110, conductive material migrates through or on a portion of ion conductor 112 to form an electrodeposit (e.g., electrodeposit 118) at or near the more negative of electrodes 108 and 110. The term “electrodeposit” as used herein means any area within or on the ion conductor that has an increased concentration of reduced metal or other conductive material compared to the concentration of such material in the bulk ion conductor material. Electrodeposits 118 may have significant growth parallel to as well as normal to the electrolyte surface.

In the absence of any insulating barriers, which are discussed in more detail below, the threshold voltage required to grow the electrodeposit is approximately the potential at which oxidation of the anode and metal ion reduction at the cathode occurs of the system, typically a few hundred millivolts. If the same voltage is applied in reverse, the electrodeposit will dissolve back into the ion conductor.

Referring again to FIG. 1, substrate 120 may include any suitable material.

For example, substrate 120 may include semiconductor, conductive, semiinsulative, insulating material, or any combination of such materials. In accordance with one embodiment of the invention, substrate 120 includes a semiconductor material such as silicon as is commonly used in the manufacture of semiconductor devices. Because the structures of the present invention can be formed over insulating or other materials, the structures are easily integrated with microelectronic or other devices and are particularly well suited for applications where substrate (e.g., semiconductor material) space is a premium.

In accordance with exemplary embodiments of the invention, one of electrodes 108 and 110 is formed of a material including a metal that dissolves in ion conductor 112 when a sufficient bias (V≧V_{T}) is applied across the electrodes (oxidizable or soluble electrode) and the other electrode is relatively inert and does not dissolve during operation of the device (inert or indifferent electrode). For example, electrode 108 may be an anode during a deposit 118 growth process and be comprised of a material including silver that dissolves in ion conductor 112 and electrode 110 may be a cathode during the deposit growth process and be comprised of an inert material such as aluminum, tungsten, nickel, molybdenum, platinum, gold, chromium, palladium, copper, all their alloys and metal silicides, doped silicon, and the like. Having at least one electrode formed of a material including a metal which dissolves in ion conductor 112 facilitates maintaining a desired dissolved metal concentration within ion conductor 112, which in turn facilitates rapid and stable electrodeposit 118 formation within ion conductor 112. Furthermore, use of an inert material for the other electrode (cathode during an electrodeposit growth step) facilitates electrodissolution of any electrodeposit that may have formed. Various other configurations of ion conductor 112 suitable for use with the present invention are discussed in U.S. Pat. No. 6,63,5914, entitled Microelectronic Programmable Device And Methods Of Forming And Programming The Same, issued to Kozicki et al. on Oct. 21, 2003, the entire content of which is hereby incorporated herein by reference.

Ion conductor 112 is formed of material that conducts ions upon application of a sufficient voltage. Suitable materials for ion conductor 112 include glasses, plastics, and semiconductor materials. In one exemplary embodiment of the invention, ion conductor 112 is formed of chalcogenide material.

Ion conductor 112 also suitably includes dissolved conductive material. For example, ion conductor 112 may comprise a solid solution that includes dissolved metals and/or metal ions. In accordance with one exemplary embodiment of the invention, conductor 112 includes metal and/or metal ions dissolved in chalcogenide glass. An exemplary chalcogenide glass with dissolved metal in accordance with the present invention includes a solid solution of AsₓS₁₋ₓ—Ag, GeₓSe₁₋ₓ—Ag, GeₓS₁₋ₓ—Ag, AsₓS₁₋ₓ—Cu, GeₓSe₁₋ₓ—Cu, GeₓS₁₋ₓ—Cu, where x ranges from about 0.1 to about 0.5, other chalcogenide materials including silver, copper, zinc, combinations of these materials, and the like.

In accordance with one particular exemplary embodiment of the invention, ion conductor 112 includes a germanium-selenide glass with about 30 to about 40 atomic percent silver diffused in the glass (e.g., Ag_{0.33}Ge_{0.20}Se_{0.47}). Additional ion conductor materials and methods of forming the ion conductor are discussed in U.S. Pat. No. 6,63,5914, entitled Microelectronic Programmable Device And Methods Of Forming And Programming The Same, issued to Kozicki et al. on Oct. 21, 2003.

Contacts (not illustrated) may suitably be electrically coupled to one or more electrodes 108, 110 to facilitate forming electrical contact to the respective electrode.

The contacts may be formed of any conductive material and are preferably formed of a metal such as aluminum, aluminum alloys, tungsten, or copper. In addition, structures and devices in accordance with the present invention may include additional insulating and/or encapsulating layers as are typically used in the manufacture of MEMS devices.

Support 102 may be formed on any suitable material. In accordance with various exemplary embodiments of the invention, support 102 is formed of insulating material such as silicon oxide, silicon nitride, silicon oxynitride, polymeric materials such as polyimide or parylene, or any combination thereof.

Base 104 and element 106 may be formed of any suitable material such as those materials typically used to form similar elements in micromechanical and microelectromechanical devices. In accordance with exemplary embodiments of the invention, base 104 and element 106 are formed of polycrystalline silicon (polysilicon), doped crystalline silicon, silicon carbide, silicon nitride carbide, diamond, quartz, ceramic, or polysilicon germanium.

Optional barrier layers 114 and/or 116 may include a material that restricts migration of ions between conductor 112 and the electrodes and/or that affects the threshold voltage required to form the electrodeposit. In accordance with exemplary embodiments of the invention, a barrier layer includes conducting material such as titanium nitride, titanium tungsten, a combination thereof, or the like. Use of a conducting barrier allows for the “indifferent” electrode to be formed of oxidizable material because the barrier prevents diffusion of the electrode material to the ion conductor. The diffusion barrier may also serve to prevent undesired electrodeposit growth within a portion of the structure. In accordance other embodiments of the invention, the barrier material includes an insulating material. Inclusion of an insulating material increases the voltage required to reduce the resistance of the device. In accordance with yet other exemplary embodiments of the invention, the barrier includes material that conducts ions, but which is relatively resistant to the conduction of electrons. Use of such material may reduce undesired plating at an electrode and increase the thermal stability of the device.

Although illustrated with barrier layers associated with each electrode, devices and structures of the invention may include only one barrier layer between one electrode and the ion conductor. For example, a barrier may be present between electrode 108 and ion conductor 112 and no barrier may be present between electrode 110 and ion conductor 112.

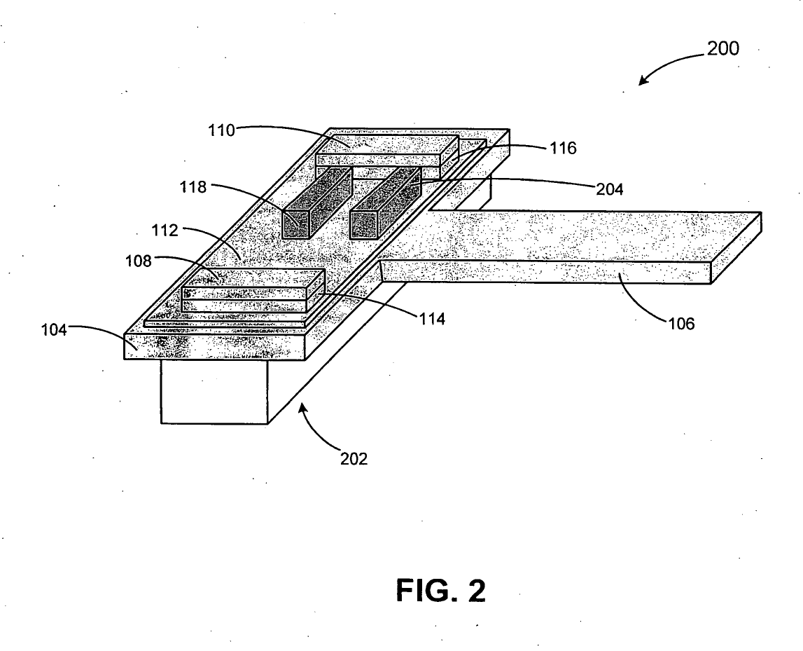

FIG. 2 illustrates another device 200 in accordance with the present invention. Device 200 is similar to device 100, except device 200 includes a region 202, which undercuts base 104 and includes an additional electrodeposit 204 formed overlying undercut region 202. Although FIGS. 1 and 2 respectively illustrate devices including one and two electrodeposits, those skill in the art will appreciate that devices in accordance with this invention may include any number of electrodeposits and that the number of deposits formed may depend on factors such as applied voltage, ion conductor composition, number of electrodes, and the like. Furthermore, for structures that include an undercut region, one or more electrodeposits may be formed over the undercut regions and/or over support 102.

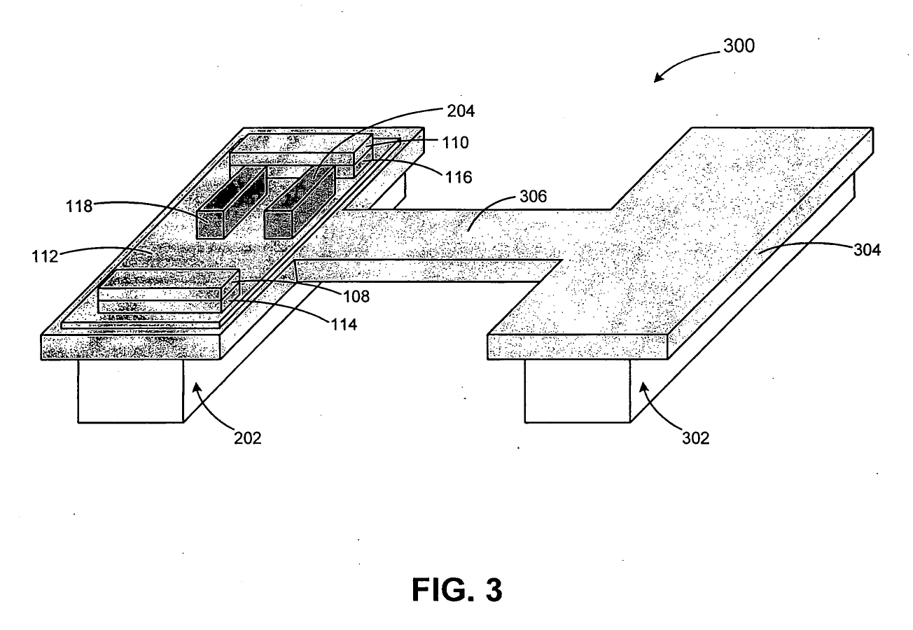

FIG. 3 illustrates yet another device 300 in accordance with the present invention. Device 300 is similar to device 200, except that device 300 includes a second support 302 and a second base 304, such that element 306 forms a beam between base 104 and base 306.

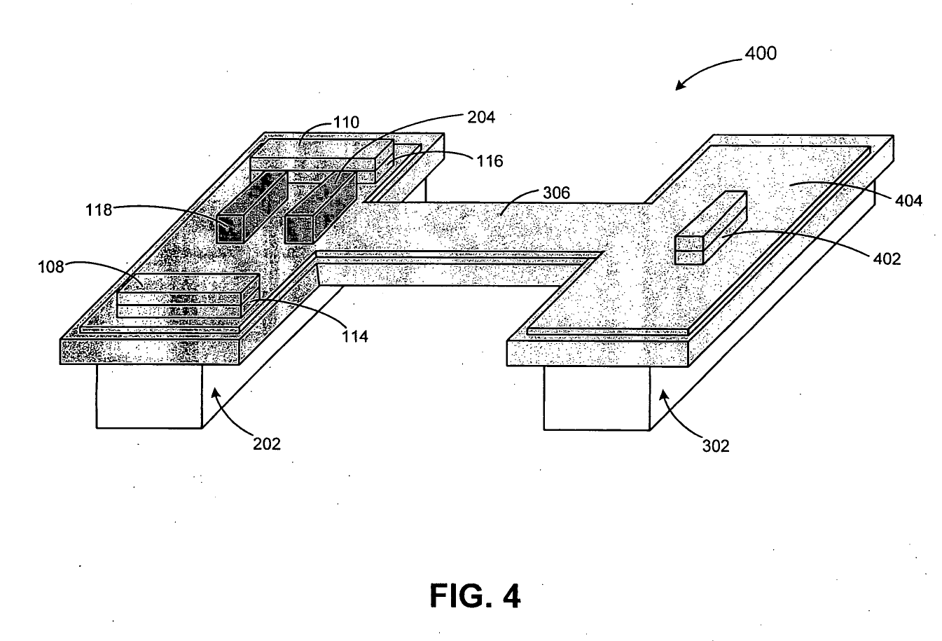

FIG. 4 illustrates another device 400 in accordance with the present invention.

Structure 400 is similar to structure 300, except structure 400 includes an additional electrode 402 and ion conductor 404 spans underneath electrode 402 over element 306.

In accordance with one aspect of this invention, electrodes 108, 110 are inert electrodes, and electrode 402 is a soluble electrode. Although illustrated with on soluble electrode on one side of element 106 and two inert electrodes on another side of element 106, devices in accordance with the present invention may include alternative electrode configurations. For example, devices may include one soluble and two inert electrodes all located on the same side of element 106, wherein the distance between the soluble electrode and any of the inert electrodes is greater than the distance between the inert electrodes. Alternatively, multiple elements (resonator array) may have a soluble electrode in common.

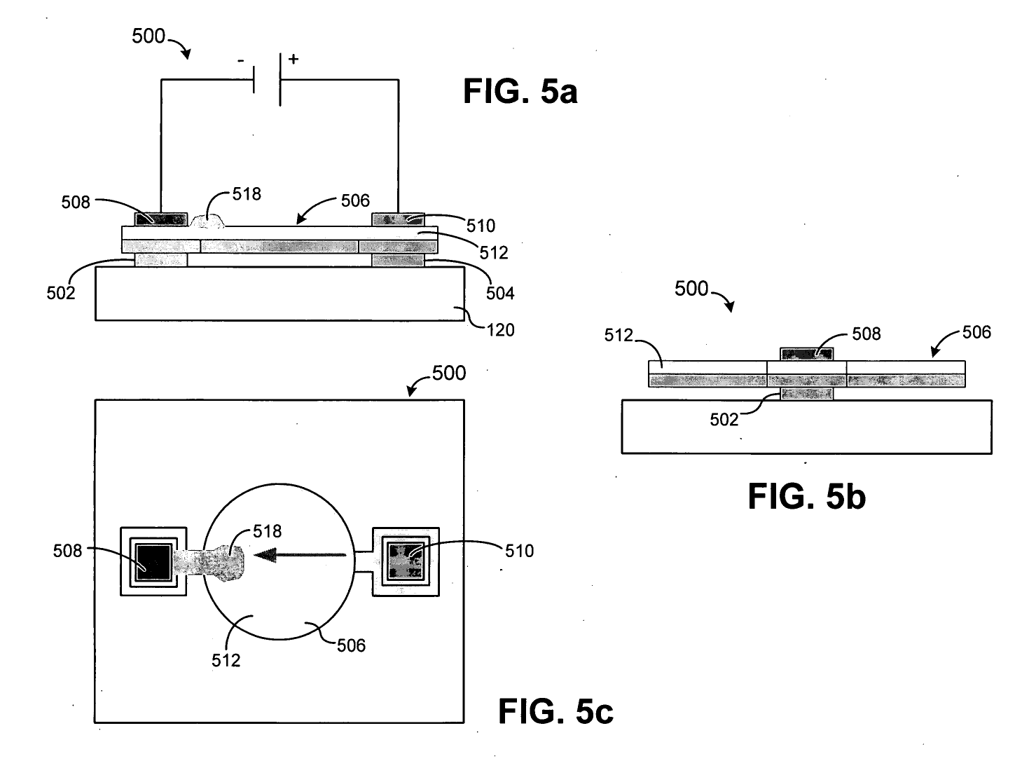

FIGS. 5(a)-5(c) respectively illustrate front, side, and top views of a device 500 in accordance with yet another embodiment of the invention. Device 500 is a suspended disk or ring-type resonators, which includes a movable element suspended by a number of tethers. The tethers are connected to anchors which include a soluble electrode and an inert electrode. In the illustrated case, device 500 includes supports 502, 504, mechanical element 506, electrodes 508, 510, and ion conductor. A conductive region 518 is formed overlying mechanical element 506. However, conductive regions may alternatively be formed proximate the mechanical element as described above in connection with the devices illustrated in FIGS. 1-4.

Referring again to FIG. 1, in accordance with one exemplary embodiment of the invention, a device in accordance with the present invention may be formed as follows. Support 102, base 104, and element 106 may be formed according to techniques know in the art. For example, material (e.g., silicon oxide) for support 102 and base 104 and element 106 material (e.g., polysilicon) may be deposited onto a surface of substrate 120. The polysilicon layer may then be patterned and etched to form base 104 and element 106.

Glass material for ion conductor 112 is then formed overlying the polysilicon material and metal is introduced into the glass material using photodissolution. By way of one particular example, a 50 nm layer of Ge_{0.20-0.40}Se_{0.60-0.82} is deposited onto the surface of the polysilicon material, and the Ge—Se layer is covered with about 20 nm of silver. The silver is dissolved into the Ge—Se glass by exposing the silver to a light source having a wavelength of about 405 nm and a power density of about 5 mW/cm² for about ten minutes. Any excess silver is then removed using a Fe(NO₃)₃ solution. The ion conductor material is then patterned an etched using RIE etching (e.g., CF₄+O₂) or wet etching (e.g., using NaOH:IPA:DI). Next electrodes 108 and 110 are formed on the surface of ion conductor 112 using a suitable deposition and etch process.

Finally, support 102 is formed and mechanical element 106 is released by etching the silicon oxide material, using an anisotropic etch, to form the support. If desired, a suitable etch mask such as parylene can be deposited and patterned to protect various portions of the device. Structures 200-400 can be formed in a similar manner, except material for support 102 is removed using an isotropic etch process rather than an anisotropic etch process.

Referring to FIG. 1-4, a resonant frequency or other mechanical attribute of element 106 may be altered by growing an electrodeposit on base 104 near element 106 (in the case of device 500, the electrodeposit is grown overlying the element). By way of specific example, with reference to FIGS. 1-3 a silver electrodeposit 118 in a Ag—Ge—Se glass, will form upon application of a bias between electrode 108 and 110 above approximately 300 mV. The electron current flow from the inert electrode reduces the excess metal due to the ion flux and hence a silver-rich electrodeposit 118 is formed on or in electrolyte 112. This amount of electrodeposited material (metal in excess of the starting composition of the electrolyte) is determined by the ion current magnitude and the time the current is allowed to flow. The electrodeposition process is reversible upon application of a reverse bias which makes the electrodeposit the oxidizable anode and re-plates the excess silver back onto the silver electrode.

With reference to FIG. 4, an electrodeposit is formed between electrodes 108 and 110 in a similar manner. Specifically, a voltage is applied to electrodes 108 and 402, and a relative bias between electrodes 108 and 402 and electrode 110 is a few hundred millivolts—e.g., about 300 mV. In this case, electrodeposit 118 forms proximate mechanical element 106, between the two inert electrodes 108 and 110.

In accordance with various embodiments of the invention, such as those illustrated in FIGS. 1-4, a surface topography of an ion conductor can be patterned (e.g., with grooves) to direct the growth of the electrodeposit. This may be particularly desirable for devices such as device 400, where the soluble electrode is on an opposite side of a movable element from the inert electrode(s).

In addition to modifying the ion conductor topography, the ion conductor can also be patterned to only be in selected locations to direct the growth of the electrodeposit. Other options to direct the growth of the electrodeposit include altering the surface topography (e.g., with grooves) of the ion conductor and then depositing the ion conductor layers on top. Various of these techniques can be used in conjuction.

Although the present invention is set forth herein in the context of the appended drawing figures, it should be appreciated that the invention is not limited to the specific form shown. For example, while the microelectromechanical structures are conveniently described above in connection with beam, cantilever, and suspended ring elements, the invention is not so limited. Furthermore, although the devices are illustrated as including various buffer or barrier layers, such layers are not required to practice the invention. Furthermore, although a limited number of examples are provided herein, this invention can be applied to any vibrating element employed as sensors, resonators, and oscillators, which consists of a movable vibrating element attached to a base and underlying substrate. Various other modifications, variations, and enhancements in the design and arrangement of the method and apparatus set forth herein, may be made without departing from the spirit and scope of the present invention as set forth in the appended claims.

1. A microelectromechanical device comprising:
a base;
a movable element coupled to the base;
an ion conductor formed on the base;
a soluble electrode proximate the ion conductor; and
a first inert electrode proximate the ion conductor.

2. The microelectromechanical device of claim 1, further comprising a second inert electrode on the ion conductor.

3 The microelectromechanical device of claim 2, wherein the first inert electrode and the second inert electrode are formed on one side of the movable element and the soluble electrode is formed on the other side of the movable element.

4 The microelectromechanical device of claim 1, wherein the first inert electrode and the soluble electrode are formed on the same side of the movable element.

5. The microelectromechanical device of claim 1, wherein the ion conductor comprises a solid solution selected from the group consisting of AsₓS₁₋ₓ—Ag, GeₓSe₁₋ₓ—Ag, GeₓS₁₋ₓ—Ag, AsₓS₁₋ₓ—Cu, GeₓSe₁₋ₓCu, GeₓS₁₋ₓ—Cu, where x ranges from about 0.1 to about 0.5.

6. The microelectromechanical device of claim 1, wherein the ion conductor comprises a glass having a composition of Ge_{0.17}Se_{0.83} to Ge_{0.25}Se_{0.75}.

7. The microelectromechanical device of claim 1, further comprising a barrier layer between at least one of the first inert electrode and the soluble electrode and the ion conductor.

8. The microelectromechanical device of claim 7, wherein the barrier layer comprises a conductive material.

9. The microelectromechanical device of claim 7, wherein the barrier layer comprises an insulating material.

10. The microelectromechanical device of claim 1, wherein the movable element comprises a material selected from the group consisting of polycrystalline silicon, doped crystalline silicon, silicon carbide, silicon nitride carbide, diamond, quartz, ceramic, and polysilicon germanium.

11. The microelectromechanical device of claim 1, wherein the inert electrode comprises a material selected from the group consisting of aluminum, tungsten, nickel, molybdenum, platinum, gold, chromium, palladium,. copper, all their alloys and metal silicides and doped silicon.

12. The microelectromechanical device of claim 1, wherein the soluble electrode comprises silver.

13. A resonator comprising the device of claim 1.

14. A resonator comprising the device of claim 3.

15. A method of tuning a microelectromechanical device, the method comprising the steps of:
providing a base;
providing a movable element coupled to the base;
providing an ion conductor overlying at least a portion of the base;
providing electrodes overlying the ion conductor; and
applying a bias across the electrodes to form an electrodeposit overlying at least a potion of the base.

16. The method of tuning a microelectromechanical device of claim 15, wherein the step of providing an ion conductor comprises supplying an ion conductor overlying at least a portion of the movable element.

17. The method of tuning a microelectromechanical device of claim 15, wherein the step of providing electrodes comprises forming one soluble electrode on one side of the movable element and two inert electrodes on an opposite side of the movable element.

18. The method of tuning a microelectromechanical device of claim 15, wherein the step of applying comprises applying a first voltage to a first inert and a soluble electrode and a second voltage to a second inert electrode.

19. A method of forming a tunable microelectromechanical device, the method comprising the steps of:
depositing base material;
depositing polycrystalline silicon material overlying the base material;
forming a base and a movable element from the polysilicon material;
forming an ion conductor overlying the base; and
forming electrodes overlying the ion conductor.

20. The method of claim 19, wherein the step of forming a base and a movable element comprises forming a movable element of a material selected from the group consisting of polycrystalline silicon, doped crystalline silicon, silicon carbide, silicon nitride carbide, diamond, quartz, ceramic, and polysilicon germanium.

21. The method of claim 19, wherein the step of forming electrodes comprises the step of forming an inert electrode from a material selected from the group consisting of aluminum, tungsten, nickel, molybdenum, platinum, gold, chromium, palladium, copper, all their alloys and metal silicides and doped silicon.

22. The method of claim 19, further comprising isotropically etching the base material to form an undercut region beneath a portion of the base.

23. The method of claim 19, further comprising controlling a growth route of the electrodeposit by modifying the ion conductor surface topography.

24. The method of claim 19, further comprising controlling a growth route of the electrodeposit by modifying the surface topography of layers underneath the ion conductor.

25. The method of claim 19, further comprising controlling a growth rout of an electrodeposit be patterning the ion conductor to form the ion conductor in specific areas.
